(19) United States
(12) Patent Application Publication
(10) Pub. No.: US 2022/0407494 A1
(43) Pub. Date: Dec. 22, 2022

(54) ACOUSTIC WAVE DEVICE AND METHOD OF MANUFACTURING THE SAME

(71) Applicant: Epicmems(Xiamen) Co., Ltd., Fujian (CN)

(72) Inventors: Bohua PENG, Fujian (CN); Ping LI, Fujian (CN); Nianchu HU, Fujian (CN); Bin JIA, Fujian (CN)

(73) Assignee: Epicmems(Xiamen) Co., Ltd., Fujian (CN)

(21) Appl. No.: 17/779,251

(22) PCT Filed: Nov. 25, 2019
(86) PCT No.: PCT/CN2019/120656

§ 371 Date: May 24, 2022

(51) Int. Cl. H03H 9/02; H03H 9/13; H03H 3/02; H03H 9/17; H03H 9/54; H03H 9/70

(52) U.S. Cl. CPC H03H 9/02118; H03H 9/13; H03H 3/02; H03H 9/17; H03H 9/54; H03H 9/706

(57) ABSTRACT

An acoustic wave device including: a POI structure including: a material layer where a high acoustic velocity layer and a low acoustic velocity layer are alternate, a substrate is a lowermost high acoustic velocity layer; a first piezoelectric layer located above the material layer, wherein a layer adjacent to the first piezoelectric layer is referred to as a surface low acoustic velocity layer; wherein an acoustic velocity of a bulk wave propagated in the high acoustic velocity layer and the low high acoustic velocity layer is higher than and lower than an acoustic velocity of a bulk wave of the first piezoelectric layer, respectively. The POI structure includes at least two regions, a first device having a resonance of a first vibration mode is manufactured in the first region, and a second device having a resonance of a second vibration mode is manufactured in a second region.

### CROSS REFERENCE

This application is a National Stage Application of International Application No. PCT/CN2019/120656, filed on Nov. 25, 2019, entitled “ACOUSTIC WAVE DEVICE AND METHOD OF MANUFACTURING THE SAME”, which is incorporated herein by reference in their entirety.

### TECHNICAL FIELD

The present disclosure relates to a field of communication device technology, and in particular, to an acoustic wave device and a method of manufacturing the same.

### BACKGROUND

An acoustic wave filter may be used in a high frequency circuit, for example, it may be used as a bandpass filter. An acoustic wave filter is composed of several acoustic wave resonators.

In recent years, filters, duplexers and the like with an acoustic wave resonator as a basic unit have higher degree of miniaturization, higher frequency and broader broadband. The acoustic wave resonators may be generally divided into surface acoustic wave (SAW) devices and bulk acoustic wave (BAW) devices based on their vibration modes. The SAW device is not applicable for a high frequency above 2.5 GHz due to limitations of an inter-digital transducer (IDT), whose line width is too small to manufacture and whose electrode loss is great. The BAW device is generally of a ladder structure and has a larger area compared with a double mode surface acoustic wave (DMS) device, and thus is limited in miniaturization. In addition, a distance between the resonators is too close, thus it is easier to generate coupling due to a leakage of the acoustic waves, and deviations may occur in rejection and isolation.

With the development of the mobile communication to 5G, there are more and more frequency bands for communication, and different frequency bands have different requirements for insertion loss and bandwidth. This also puts forward diversified requirements for the filter technology.

### SUMMARY

According to the present disclosure, there is provided an acoustic wave device and a method of manufacturing the same, so as to reduce the coupling interference between devices, improve the rejection and isolation of a filter or a duplexer, and further reduce the size of the device to meet the requirements of miniaturization.

According to an aspect of the present disclosure, an acoustic wave device is provided, including: a POI structure including: a material layer where a high acoustic velocity layer and a low acoustic velocity layer are alternate, wherein a substrate is a lowermost high acoustic velocity layer; and a first piezoelectric layer located above the material layer where the high acoustic velocity layer and the low acoustic velocity layer are alternate, wherein a layer adjacent to the first piezoelectric layer is referred to as a surface low acoustic velocity layer; wherein an acoustic velocity of a bulk wave propagated in the high acoustic velocity layer is higher than an acoustic velocity of a bulk wave of the first piezoelectric layer, and an acoustic velocity of a bulk wave propagated in the low acoustic velocity layer is lower than the acoustic velocity of the bulk wave of the first piezoelectric layer; wherein the POI structure includes at least two regions, the two regions are respectively a first region and a second region, a first device having a resonance of a first vibration mode is manufactured in the first region, and a second device having a resonance of a second vibration mode is manufactured in the second region.

According to an embodiment of the present disclosure, the first vibration mode and the second vibration mode are a combination of any two types of a bulk acoustic wave (BAW) vibration mode, a surface acoustic wave (SAW) vibration mode, and a contour mode resonator (CMR) mode.

According to an embodiment of the present disclosure, the first vibration mode and the second vibration mode are different vibration modes.

According to an embodiment of the present disclosure, the first piezoelectric layer is located above the surface low acoustic velocity layer in the second region; an inter-digital transducer layer is located above the first piezoelectric layer; and a piezoelectric structure is located above the surface low acoustic velocity layer in the first region, there is a distance existing between the piezoelectric structure and the first piezoelectric layer, and a first cavity is located below the piezoelectric structure; wherein the piezoelectric structure includes a lower electrode layer, a second piezoelectric layer, and an upper electrode layer that are stacked in sequence.

According to an embodiment of the present disclosure, the upper electrode layer is of a thin film structure or an inter-digital transducer structure.

According to an embodiment of the present disclosure, a second cavity is located below the first piezoelectric layer, and the second cavity is formed by releasing a portion of the surface low acoustic velocity layer and the substrate located below the first piezoelectric layer.

According to an embodiment of the present disclosure, an upper surface of the piezoelectric structure and the inter-digital transducer layer are both covered with a dielectric layer; the second region includes two subregions, which are respectively a first subregion and a second subregion, the inter-digital transducer layer is located in the first subregion, another inter-digital transducer layer is located in the second subregion, and the another inter-digital transducer layer is sequentially covered with a dielectric layer and a metal connection layer.

According to an embodiment of the present disclosure, a metal layer is further arranged on the inter-digital transducer layer, and the metal layer is located at an edge of an inter-digital transducer arm of the inter-digital transducer layer; or a second high acoustic velocity layer is formed in a middle region of the inter-digital transducer layer, and an acoustic velocity of a bulk wave propagated in the second high acoustic velocity layer is higher than the acoustic velocity of the bulk wave of the first piezoelectric layer.

According to an embodiment of the present disclosure, the first cavity is formed by releasing a portion of the surface low acoustic velocity layer and the substrate located below the piezoelectric structure; or the first cavity is formed by releasing a portion of the surface low acoustic velocity layer located below the piezoelectric structure, and a periphery of the first cavity located below the piezoelectric structure is a barrier layer.

According to an embodiment of the present disclosure, the device in the first region is a bulk acoustic wave device, the bulk acoustic wave device is of an SMR structure, an acoustic reflection layer including a low acoustic impedance material layer and a high acoustic impedance material layer that are stacked alternately is located above the first piezoelectric layer in the first region; the piezoelectric structure is located above the low acoustic impedance material layer of the acoustic reflection layer; or the device in the first region is a high overtone acoustic resonator, and the device in the second region is one or a combination of the following devices: a resonator of a bulk acoustic wave (BAW) vibration mode, a resonator of a surface acoustic wave (SAW) vibration mode, and a contour mode resonator (CMR), wherein the resonator of a bulk acoustic wave (BAW) vibration mode includes one or a combination of the following resonators: a film bulk acoustic resonator (FBAR) and a solid mounted resonator (SMR).

According to an embodiment of the present disclosure, all or a portion of the devices in at least two regions of the acoustic wave devices are served as filters or duplexers.

According to an embodiment of the present disclosure, the POI structure includes: a substrate, a temperature compensation layer, a first piezoelectric layer. Optionally, a multi-layer of a high acoustic velocity layer and a low acoustic velocity layer alternately stacked may also be provided between the temperature compensation layer and the first piezoelectric layer, and a layer adjacent to the first piezoelectric layer is the surface low acoustic velocity layer.

According to another aspect of the present disclosure, a method of manufacturing an acoustic wave device is provided, including:

manufacturing a POI structure, wherein the POI structure includes: a material layer where a high acoustic velocity layer and a low acoustic velocity layer are alternate, and a substrate is a lowermost high acoustic velocity layer; and a first piezoelectric layer located above the material layer where the high acoustic velocity layer and the low acoustic velocity layer are alternate, and a layer adjacent to the first piezoelectric layer is referred to as a surface low acoustic velocity layer; wherein an acoustic velocity of a bulk wave propagated in the high acoustic velocity layer is higher than an acoustic velocity of a bulk wave of the first piezoelectric layer, and an acoustic velocity of a bulk wave propagated in the low acoustic velocity layer is lower than the acoustic velocity of the bulk wave of the first piezoelectric layer;

wherein the POI structure includes at least two regions, the two regions are respectively a first region and a second region, a first device having a resonance of a first vibration mode is manufactured in the first region, and a second device having a resonance of a second vibration mode is manufactured in the second region.

It may be seen from the above technical solutions that the acoustic wave device and the method of manufacturing the same provided by the present disclosure have at least the following advantageous effects:

(1) Comparing with a piezoelectric substrate of a conventional SAW device such as lithium niobate or lithium tantalate, by using the POI structure, an acoustic wave formed by a device vibration only propagates within the piezoelectric layer and the low acoustic velocity layer without leaking into a deeper substrate layer, and an energy leakage in a longitudinal direction is rejected. However, a portion of the energy still propagates outwardly in a lateral direction. Devices of at least two modes are integrated on one same device based on at least two regions, the implementation manner is simple and convenient. Moreover, by controlling the two modes to be different, the vibration modes or propagation directions are different, such that a coupling interference between devices in different regions may be reduced, and the rejection and isolation of filters or duplexers formed by a combination of devices in different regions may be improved. In this way, the device size may also be reduced, the costs may be reduced, and the requirements of communication miniaturization may be satisfied.

Since piezoelectric materials of the same material and the same thickness do not need to be used for the devices of various vibration modes in the present disclosure, the degree of design freedom is improved. This is helpful to manufacture products that satisfy different bandwidths, different insertion losses, isolations, different power capacities, etc.

### BRIEF DESCRIPTION OF THE DRAWINGS

FIG. 1 is a schematic cross-sectional structural diagram of an acoustic wave device according to a first embodiment of the present disclosure.

FIG. 2 is a schematic top view structural diagram of the acoustic wave device according to a first embodiment of the present disclosure.

FIG. 3 is a schematic cross-sectional structural diagram of an acoustic wave device according to a second embodiment of the present disclosure.

FIG. 4 is a schematic cross-sectional structural diagram of an acoustic wave device according to a third embodiment of the present disclosure.

FIG. 5 is a schematic cross-sectional structural diagram of an acoustic wave device according to a fourth embodiment of the present disclosure.

FIG. 6 is a schematic cross-sectional structural diagram of an acoustic wave device according to a fifth embodiment of the present disclosure.

FIG. 7 is a schematic cross-sectional structural diagram of an acoustic wave device according to a sixth embodiment of the present disclosure.

FIG. 8 is a schematic cross-sectional structural diagram of an acoustic wave device according to a seventh embodiment of the present disclosure.

FIG. 9 is a schematic top view structural diagram of an acoustic wave device according to an eighth embodiment of the present disclosure.

FIG. 10 is a method of manufacturing the acoustic wave device according to the ninth embodiment of the present disclosure.

### REFERENCE SIGN LIST

11—substrate;
12—temperature compensation layer;
13—first piezoelectric layer;
14—inter-digital transducer layer;
15—metal layer;
16—reflection grating;
21—lower electrode layer;
22—upper electrode layer;
23—second piezoelectric layer;
D1—first region;
D2—second region;
3—first cavity;
4—barrier layer;
5—acoustic reflection layer;
51—low acoustic impedance material layer;
52—high acoustic impedance material layer;
22′—upper electrode layer of inter-digital transducer structure;
6—second cavity;
14′—inter-digital transducer layer of a third resonance portion;
7—dielectric layer;
8—metal connection layer;
9—high acoustic velocity layer.

### DETAILED DESCRIPTION OF EMBODIMENTS

In order to make objectives, technical solutions and advantages of the present disclosure more apparent, the present disclosure will be further described in detail below with reference to the specific embodiments and the accompanying drawings.

An SAW device is used to convert an electrical energy to an acoustic energy, or oppositely convert an acoustic energy to an electrical energy by using an inter-digital transducer. A piezoelectric substrate, two opposing busbars at two different potentials, and two sets of electrodes connected to the two busbars are used in the inter-digital transducer. Due to an inverse piezoelectric effect, an acoustic wave source is provided in an electric field between two consecutive electrodes at different potentials. Oppositely, if an incident wave is received by a transducer, a charge is generated in the electrodes due to the piezoelectric effect, and a resonator is obtained by arranging the transducer between two reflection gratings.

Similar to the SAW device, a resonance is generated in a BAW device relying on the piezoelectric effect of a piezoelectric material. In general, the BAW device has a higher Q value and a better power withstand capability, however, an equivalent coupling coefficient (determining a filter bandwidth) of the BAW device is slightly smaller than an equivalent coupling coefficient of the SAW device. A BAW resonator generally consists of an upper electrode layer, a piezoelectric layer, and a lower electrode layer to form a sandwich structure and the resonance is generated. An air cavity or an acoustic reflection layer is located below the lower electrode, and a resonance region exists inside the piezoelectric layer rather than on a surface of the piezoelectric layer.

In addition, a lamb mode of the piezoelectric layer may also be used to manufacture the resonator such as a contour mode resonator (CMR), but there exist disadvantages that the equivalent coupling coefficient (k2eff) is small, and the Q value is not high.

The acoustic wave filtering technologies such as BAW, SAW and CMR have their own advantages and disadvantages, and therefore it has become a technical problem for the industry to overcome how to integrate these technologies to one same chip. It is of great value to solve the above technical problems for manufacturing products that satisfy different bandwidths, different insertion losses, isolations, different power capacities, etc.

In some studies, an acoustic wave device is manufactured by growing different material layers on a silicon substrate or by a bonding between different substrates. This requires a plurality of process steps, while restricting different resonators from using the same piezoelectric material, which is not conducive to an industrialized popularization of devices, and thus has a limited scope of application. Some studies mention that two filters of a duplexer respectively use different vibration modes, however, they are manufactured based on different chips, and vibration modes of the respective resonators in the filters are the same. In some studies, a filter is constituted by resonators of different vibration modes based on one same substrate, however, only a combination of resonators of different vibration modes CMR+BAW is proposed, whose application scope is limited.

The present disclosure provides an acoustic wave device and a method of manufacturing the same. By using a POI structure, two devices are integrated on one same substrate. A piezoelectric film layer carried by the POI structure itself is used as a piezoelectric layer of one device, and a temperature compensation layer carried by the POI structure itself is used as a sacrificial layer of the other device, which effectively controls requirements of different devices for film thickness, roughness, crystal orientation, etc., while reducing materials and layers used to integrate the two devices, thereby effectively reducing manufacturing costs.

The acoustic wave device of the present disclosure includes: a POI structure including: a material layer where a high acoustic velocity layer and a low acoustic velocity layer are alternate, wherein a substrate is a lowermost high acoustic velocity layer; and a first piezoelectric layer located above the material layer where the high acoustic velocity layer and the low acoustic velocity layer are alternate, wherein a layer adjacent to the first piezoelectric layer is referred to as a surface low acoustic velocity layer; wherein an acoustic velocity of a bulk wave propagated in the high acoustic velocity layer is higher than an acoustic velocity of a bulk wave of the first piezoelectric layer, and an acoustic velocity of a bulk wave propagated in the low acoustic velocity layer is lower than the acoustic velocity of the bulk wave of the first piezoelectric layer;

the POI structure includes at least two regions, the two regions are respectively a first region and a second region, a first device having a resonance of a first vibration mode is manufactured in the first region, and a second device having a resonance of a second vibration mode is manufactured in the second region.

In an embodiment of the present disclosure, the first region is a resonator having a first vibration mode, such as a resonator of a bulk acoustic wave (BAW) vibration mode, and the second region is a resonator having a second vibration mode, such as a resonator of a surface acoustic wave (SAW) vibration mode or a contour mode resonator (CMR). Specifically, the resonator of a bulk acoustic wave vibration mode may be a film bulk acoustic resonator (FBAR), such as the structure illustrated in the first and second embodiments, and a combination manner of the devices in the first region and the second region is: FBAR (a type of BAW)+SAW. The resonator of a bulk acoustic wave vibration mode may also be a solid mounted resonator (SMR), such as the structure illustrated in the third embodiment, and a combination manner of the devices in the first region and the second region is: SMR (belonging to a type of BAW)+SAW.

Certainly, the two vibration modes may be combinations of any two types of: a bulk acoustic wave (BAW) vibration mode, a surface acoustic wave (SAW) vibration mode, and a contour mode resonator (CMR) vibration mode, and preferably the first vibration mode and the second vibration mode are different, details of which may be referred to the descriptions of the embodiments.

In an embodiment of the present disclosure, the first vibration mode and the second vibration mode are a combination of any two types of a bulk acoustic wave (BAW) vibration mode, a surface acoustic wave (SAW) vibration mode, and a contour mode resonator (CMR) mode.

In an embodiment of the present disclosure, the first vibration mode and the second vibration mode are different vibration modes.

In an embodiment of the present disclosure, the first piezoelectric layer is located above the surface low acoustic velocity layer in the second region; an inter-digital transducer layer is located above the first piezoelectric layer; and a piezoelectric structure is located above the surface low acoustic velocity layer in the first region, there is a distance existing between the piezoelectric structure and the first piezoelectric layer, and a first cavity is located below the piezoelectric structure; wherein the piezoelectric structure includes a lower electrode layer, a second piezoelectric layer, and an upper electrode layer that are stacked in sequence.

In an embodiment of the present disclosure, the upper electrode layer is of a thin film structure or an inter-digital transducer structure.

In an embodiment of the present disclosure, a second cavity is located below the first piezoelectric layer, and the second cavity is formed by releasing a portion of the surface low acoustic velocity layer and the substrate located below the first piezoelectric layer.

In an embodiment of the present disclosure, an upper surface of the piezoelectric structure and the inter-digital transducer layer are both covered with a dielectric layer; the second region includes two subregions, which are respectively a first subregion and a second subregion, the inter-digital transducer layer is located in the first subregion, another inter-digital transducer layer is located in the second subregion, and the another inter-digital transducer layer is sequentially covered with a dielectric layer and a metal connection layer.

In an embodiment of the present disclosure, a metal layer is further arranged on the inter-digital transducer layer, and the metal layer is located at an edge of an inter-digital transducer arm of the inter-digital transducer layer; or a second high acoustic velocity layer is formed in a middle region of the inter-digital transducer layer, and an acoustic velocity of a bulk wave propagated in the second high acoustic velocity layer is higher than the acoustic velocity of the bulk wave of the first piezoelectric layer.

In embodiment of the present disclosure, the first cavity is formed by releasing a portion of the surface low acoustic velocity layer and the substrate located below the piezoelectric structure; or the first cavity is formed by releasing a portion of the surface low acoustic velocity layer located below the piezoelectric structure, and a periphery of the first cavity located below the piezoelectric structure is a barrier layer.

In an embodiment of the present disclosure, the device in the first region is a bulk acoustic wave device, the bulk acoustic wave device is of an SMR structure, an acoustic reflection layer including a low acoustic impedance material layer and a high acoustic impedance material layer that are stacked alternately is located above the first piezoelectric layer in the first region; the piezoelectric structure is located above the low acoustic impedance material layer of the acoustic reflection layer; or

the device in the first region is a high overtone acoustic resonator, and the device in the second region is one or a combination of the following devices: a resonator of a bulk acoustic wave (BAW) vibration mode, a resonator of a surface acoustic wave (SAW) vibration mode, and a contour mode resonator (CMR), wherein the resonator of a bulk acoustic wave (BAW) vibration mode includes one or a combination of the following resonators: a film bulk acoustic resonator (FBAR) and a solid mounted resonator (SMR).

In an embodiment of the present disclosure, all or a portion of the devices in at least two regions of the acoustic wave devices are served as filters or duplexers.

### First Embodiment

In a first exemplary embodiment of the present disclosure, an acoustic wave device is provided.

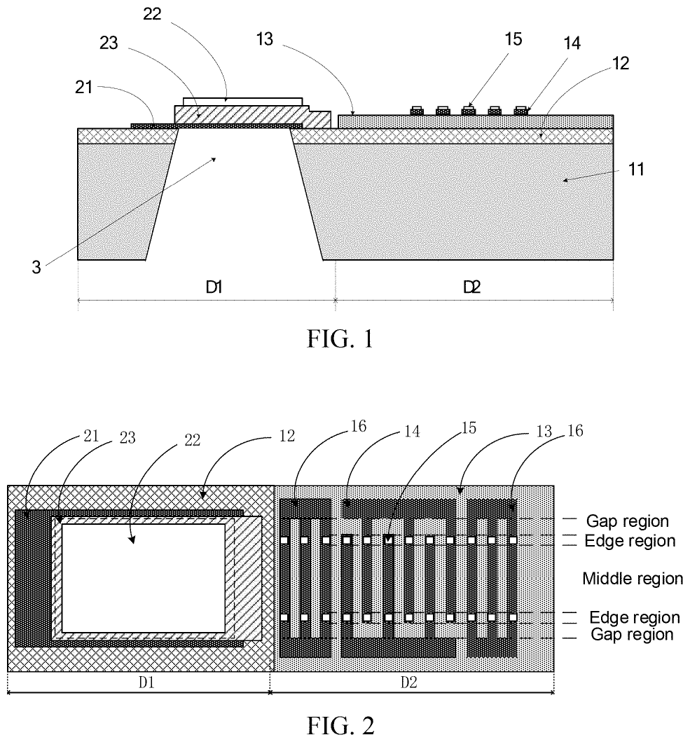

FIG. 1 is a schematic cross-sectional structural diagram of an acoustic wave device according to a first embodiment of the present disclosure. FIG. 2 is a schematic top view structural diagram of the acoustic wave device according to the first embodiment of the present disclosure.

Referring to FIG. 1 and FIG. 2, an acoustic wave device according to the present disclosure includes: a POI structure, the POI structure includes: a material layer where high acoustic velocity layers and low acoustic velocity layers are alternate, and a substrate is taken as a lowermost high acoustic velocity layer; and a piezoelectric layer located above the material layer where the high acoustic velocity layers and the low acoustic velocity layers are alternate, and a layer adjacent to the piezoelectric layer is a low acoustic velocity layer. An acoustic velocity of a bulk=wave of the high acoustic velocity layer is higher than an acoustic velocity of a bulk wave of the first piezoelectric layer, and an acoustic velocity of a bulk wave of the low acoustic velocity layer is lower than the acoustic velocity of the bulk wave of the first piezoelectric layer;

The POI structure is divided into at least two regions, wherein the two regions include a first region, in which a first device having a resonance of a first vibration mode is manufactured, and a second region, in which a second device having a resonance of a second vibration mode is manufactured.

Here, POI (piezoelectric on insulator) is shortened from a piezoelectric material on an insulating substrate.

In an embodiment of the present disclosure, the acoustic wave device includes a first region D1 and a second region D2. The first region D1 is a resonator having a first vibration mode, such as a bulk acoustic wave vibration mode, and the second region is a resonator having a second vibration mode, such as a surface acoustic wave vibration mode or a contour mode.

A thickness of a first piezoelectric layer 13 is set to a range of 0.05 to 1λ; and a thickness of a temperature compensation layer 12 is set to a range below 2λ; wherein λ represents a period of an inter-digital transducer, i.e., an acoustic wave wavelength corresponding to a resonance frequency.

In the present embodiment, as shown in FIG. 1, the acoustic wave device includes: a substrate 11; a temperature compensation layer 12 located above the substrate 11; a first piezoelectric layer 13 located above the temperature compensation layer 12 in the second region D2; an inter-digital transducer layer 14 located above the first piezoelectric layer 13;

a piezoelectric structure located above the temperature compensation layer 12 in the first region D1, there is a distance existing between the piezoelectric structure and the first piezoelectric layer 13, and a first cavity 3 is located below the piezoelectric structure;

wherein a resonator of a bulk acoustic wave (BAW) vibration mode is formed in the first region D1, and a resonator of a surface acoustic wave (SAW) vibration mode is formed in the second region D2.

In the present embodiment, the first cavity 3 is formed by releasing a portion of the temperature compensation layer 12 and the substrate 11 below the piezoelectric structure.

In an embodiment, as shown in FIG. 1, the piezoelectric structure includes a lower electrode layer 21, a second piezoelectric layer 23 and an upper electrode layer 22 that are stacked in sequence.

Various portions of the acoustic wave device will be described in detail below.

The substrate 11, the temperature compensation layer 12 and the first piezoelectric layer 13 are simultaneously included in the first region D1 and the second region D2. As an example of the POI structure, the substrate 11, the temperature compensation layer 12 and the first piezoelectric layer 13 further grow structures having different vibration modes on the above common POI structure, thereby realizing an integration of acoustic wave structures of two or more operating modes on one same substrate. In the present embodiment, as shown in FIG. 1, a portion of the substrate 11 and the temperature compensation layer 12 in the first region D1 are etched to release a space below the piezoelectric structure, a first cavity 3 is formed below the piezoelectric structure, thereby obtaining a bulk acoustic wave device, and the bulk acoustic wave device is of a film bulk acoustic resonator (FBAR) structure. In addition, the first piezoelectric layer 13 covering the temperature compensation layer 12 in the first region D1 is also partially etched, and only the first piezoelectric layer 13 in the second region is remained. In terms of a formation process, after the first piezoelectric layer 13 in the first region D1 is etched, a piezoelectric structure may be grown above the temperature compensation layer 12 in the first region, that is, the lower electrode layer 21, the second piezoelectric layer 23 and the upper electrode layer 22 are grown sequentially from bottom to top to constitute a sandwich structure of the BAW device, and then the temperature compensation layer 12 and the substrate 11 of the first region D1 are etched as described above to be released, so as to obtain the first cavity 3.

Of course, in other embodiments, the structure of the bulk acoustic wave device may also be modified, for example, the bulk acoustic wave structure in a third embodiment is a structure of a solid mounted resonator (SMR), which will be described in detail later.

In addition, in the present embodiment, the first cavity 3 is formed by etching (releasing) the substrate 11 and the temperature compensation layer 12 below the piezoelectric structure. In other embodiments, a releasing process of the first cavity may also be modified. For example, in a second embodiment, the first cavity 3 is formed by releasing the temperature compensation layer 12 below the piezoelectric structure, which will be described in detail later.

An inter-digital transducer layer 14 and a metal layer 15 are grown on a surface of the first piezoelectric layer 13 in the second region D2. In a formation process, the inter-digital transducer layer 14 may multiplex a material and a thickness of the lower electrode layer 21, or a layer of electrode material may also be grown separately to manufacture the inter-digital transducer layer 14. The metal layer 15 may multiplex a material and a thickness of the upper electrode 22, or a layer of metal material may also be grown separately to manufacture the metal layer 15. In other embodiments, as shown in a sixth embodiment, a metal layer may not be grown. A structure where a metal layer is grown has an acoustic velocity transition region as compared with a structure where no metal layer is grown. This helps to reduce an energy leakage of acoustic waves in an extension direction of an inter-digital transducer arm, effectively reject a clutter mode near a resonance frequency, and improve a Q value of the device.

Materials of the lower electrode layer 21, the upper electrode layer 22, the inter-digital transducer layer 14, and the metal layer 15 included in the acoustic wave device of the present embodiment may be, but are not limited to, metals, alloys or other conductive materials with good conductivity. For example, they may be aluminum, molybdenum, copper, gold, platinum, silver, nickel, chromium, tungsten, etc. that are compatible with semiconductor processes. Of course, the lower electrode layer, the upper electrode layer, the inter-digital transducer layer, and the metal layer may also be alloys composed of these metals.

A material of the temperature compensation layer 12 is a dielectric material, such as silicon dioxide, phosphosilicate glass, or another material having a positive frequency temperature coefficient. In addition, a dielectric coefficient of the dielectric material of the temperature compensation layer is preferably small, which helps to increase an equivalent coupling coefficient of the device.

Materials of the first piezoelectric layer 13 and the second piezoelectric layer 23 may be, but are not limited to, aluminum nitride, zinc oxide, lithium niobate, lithium tantalate, etc., or a mixture thereof.

The substrate 11 may be a semiconductor substrate such as silicon, quartz, alumina, etc.

As shown in FIG. 1 and FIG. 2, the metal layer 15 is further arranged on the inter-digital transducer layer 14, and the metal layer 15 is located at an edge of the inter-digital transducer arm of the inter-digital transducer layer 14, and is of a bump structure relative to the inter-digital transducer layer 14.

Referring to FIG. 2, the first region D1 is the bulk acoustic wave BAW device, a dotted frame represents a shape formed by etching the substrate 11 from a backside, and a region in the piezoelectric structure where the upper electrode 22, the second piezoelectric layer 23 and the lower electrode 21 are overlapped defines an effective vibration region of the device. The second region D2 is the surface acoustic wave SAW device, an upper end and a lower end of the inter-digital transducer layer 14 are busbars, a middle portion of the inter-digital transducer layer is the inter-digital transducer arm, and two sides of the inter-digital transducer 14 are reflection gratings 16. In order to highlight the inter-digital transducer layer 14, the reflection gratings 16 on the left and right sides of the inter-digital transducer layer 14 are not shown in FIG. 1. In addition, the number of the inter-digital transducer arms is only for illustrative purpose in FIG. 1 and FIG. 2, and the numbers in FIG. 1 and FIG. 2 may not be completely consistent. Referring further to FIG. 2, the inter-digital transducer arm is divided into a middle region, an edge region and a gap region, and each region is represented by ranges defined by the dotted lines in the second region in FIG. 2. Here, in the opposite two groups of inter-digital transducer arms, the metal layer 15 is grown at the edge of each group of the inter-digital transducer arms, and the metal layer 15 is also grown at a corresponding parallel position of the other group of inter-digital transducer arms. The metal layer 15 is of a bump structure relative to the inter-digital transducer layer, which is shown as a block in FIG. 2. In this way, a range between two metal layers 15 that are arranged in parallel is defined as a middle region, the metal layer 15 are located in an edge region, and a region between the metal layer 15 and busbar is defined as a gap region. Thereby, an acoustic velocity transition region from a medium acoustic velocity to a low acoustic velocity, and then from the low acoustic velocity to a high acoustic velocity is formed along the extension direction of the inter-digital transducer arm, from the middle region to the edge region, and then from the edge region to the gap region. This helps to reduce an energy leakage of the acoustic waves in the extension direction of the inter-digital transducer arm, effectively reject the clutter mode near the resonance frequency, and improve the Q value of the device.

Referring to FIG. 2, on an electrode arm of the reflection grating 16, a bump structure formed by the metal layer is also arranged at a position on one same straight line corresponding to the metal layer in the inter-digital transducer layer 14.

In this way, the first region D1 and the second region D2 together constitute the acoustic wave device having a hybrid integration of different vibration modes. The acoustic wave device may be a filter composed by including resonators of the two regions, or a duplexer or multiplexer based on filters composed of resonators having same or different vibration modes.

Here, a duplexer constituted by filters having different vibration modes is taken as an example to illustrate advantages of the above acoustic wave device. For example, the first region is the bulk acoustic wave filter, the second region is the surface acoustic wave filter, and the first and second regions together constitute the duplexer. In case that the filters in the first region and the second region use the same vibration mode, if the regions are too close between each other, a vibration leakage may easily occur. Due to a coupling between the filters, attenuation characteristics of the two and an isolation of the duplexer may become worse, and it is also not conducive for reducing a size of the device.

Here, resonators of BAW and SAW modes are integrated on the same POI structure, such that the first region D1 is the bulk acoustic wave resonator, and the vibration mode is along a direction perpendicular to the device, for example, along an up-down direction viewed referring to FIG. 1. The second region D2 is the surface acoustic wave resonator, and the vibration mode is propagated along a direction parallel to a surface of the device, for example, along a left-right direction viewed referring to FIG. 1. On one hand, differences between the vibration and propagation directions of the devices in the two regions may effectively reduce the coupling between the filters in the first region and the second region, improve the attenuation and the isolation of the entire device, shorten the distance between the two filters, and also reduce the device size.

On the other hand, as compared with the BAW, the SAW has a larger equivalent coupling coefficient (k2eff), a larger dielectric coefficient, a worse temperature coefficient of frequency (TCF) and a worse power capacity, and the SAW and the BAW complement with each other. With an integration of the resonant devices of different vibration modes on the same device, a degree of design freedom may be improved, and filters having different sizes, different bandwidths, different insertion losses, isolations, different power capacities, etc. in a plurality of regions may be manufactured separately. In addition, it also helps to complement the advantages and disadvantages of different operating modes and combine the advantages thereof, while improving the degree of design freedom. Therefore, the duplexer may better satisfy the requirements for different performances.

### Second Embodiment

In a second exemplary embodiment of the present disclosure, an acoustic wave device is provided. Compared with the first embodiment, a releasing form of the first cavity of the acoustic wave device is optimized in the second embodiment.

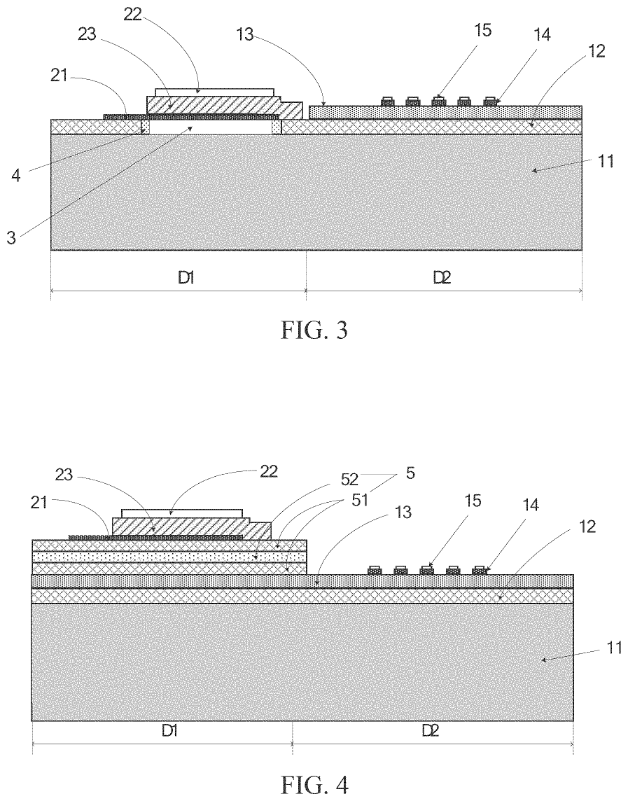

FIG. 3 is a schematic cross-sectional structural diagram of an acoustic wave device according to the second embodiment of the present disclosure.

Referring to FIG. 3, in the present embodiment, the acoustic wave device includes: a substrate 11; a temperature compensation layer 12 located above the substrate 11; a first piezoelectric layer 13 located above the temperature compensation layer 12 in a second region D2; an inter-digital transducer layer 14 located above the first piezoelectric layer 13; a metal layer 15 located above the inter-digital transducer layer 14, and the metal layer 15 is located at an edge of an inter-digital transducer arm of the inter-digital transducer layer 14;

a piezoelectric structure located above the temperature compensation layer 12 in a first region D1, there is a distance existing between the piezoelectric structure and the first piezoelectric layer 13, and a first cavity 3 is located below the piezoelectric structure;

wherein a resonator of a bulk acoustic wave (BAW) vibration mode is formed in the first region D1, and a resonator of a surface acoustic wave (SAW) vibration mode is formed in the second region D2.

In the present embodiment, the first cavity 3 is formed by releasing a portion of the temperature compensation layer 12 located below the piezoelectric structure. A periphery of the first cavity 3 is a barrier layer 4 located below the piezoelectric structure. Referring to FIG. 3, the barrier layer 4 is adjacent to an inner side of the temperature compensation layer 12 in the first region D1.

In an embodiment, as shown in FIG. 3, the piezoelectric structure includes a lower electrode layer 21, a second piezoelectric layer 23 and an upper electrode layer 22 that are stacked in sequence.

In the present embodiment, a portion of the temperature compensation layer 12, such as an annular portion, located below the piezoelectric structure in the first region D1 is etched, and an etched portion is filled with a barrier layer 4. A material of the barrier layer 4 has an etching rate different from an etching rate of a material of the temperature compensation layer 12, and a material whose etching rate differs from the etching rate from the material of the temperature compensation layer 12 largely is preferably selected as the material of the barrier layer 4. The temperature compensation layer 12 located on the inner side of the barrier layer 4 is etched as a sacrificial layer, such that a first cavity 3 is obtained by releasing a region corresponding to the sacrificial layer. Certainly, in the above formation process, a conventional planarization processing step is also included after the barrier layer is deposited.

In the acoustic wave device of the present embodiment, the first region D1 is a bulk acoustic wave BAW device, and is also of a structure of a film bulk acoustic wave resonator (FBAR), which is the same as the first embodiment.

It should be noted that, for the same portions as in the first embodiment, reference may be made to the descriptions in the first embodiment, which will not be repeated here.

In the second embodiment, the first cavity is formed by releasing the temperature compensation layer below the piezoelectric structure without releasing the substrate. Compared with the first embodiment, the bulk acoustic wave device in the second embodiment has advantage of being more robust and more reliable.

### Third Embodiment

In a third exemplary embodiment of the present disclosure, an acoustic wave device is provided. Compared with the first embodiment, a structure of a bulk acoustic wave device in a first region is modified in an acoustic wave device in the third embodiment.

FIG. 4 is a schematic cross-sectional structural diagram of an acoustic wave device according to the third embodiment of the present disclosure.

Referring to FIG. 4, in the present embodiment, the acoustic wave device includes:

a substrate 11; a temperature compensation layer 12 located above the substrate 11; a first piezoelectric layer 13 located above the temperature compensation layer 12;

an inter-digital transducer layer 14 located above the first piezoelectric layer 13 in a second region D2;

an acoustic reflection layer 5 located above the first piezoelectric layer 13 in a first region D1, which includes a low acoustic impedance material layer 51 and a high acoustic impedance material layer 52 that are alternately stacked, there is a distance existing between the acoustic reflection layer 5 and the inter-digital transducer layer 14;

a piezoelectric structure located above the low acoustic impedance material layer 51 of the acoustic reflection layer 5;

wherein a solid mounted resonator (SMR) is formed in the first region D1, and a resonator of a surface acoustic wave (SAW) vibration mode is formed in the second region D2. An acoustic wave mode corresponding to the SMR is the bulk acoustic wave.

In an embodiment, as shown in FIG. 4, the piezoelectric structure includes a lower electrode layer 21, a second piezoelectric layer 23 and an upper electrode layer 22 that are stacked in sequence.

In the present embodiment, compared with the first embodiment, the temperature compensation layer 12 and the substrate 11 located below the piezoelectric structure do not need to be released, and the acoustic reflection layer 5 is arranged between the piezoelectric structure and the temperature compensation layer, such that a POI structure formed by the temperature compensation layer 12 and the first piezoelectric layer 13 on the substrate 11, and the acoustic reflection layer 5 together constitute a Bragg reflection, thereby rejecting a propagation of an acoustic wave energy toward the substrate.

In the present embodiment, a thickness of each of the low acoustic impedance material layers 51 and the high acoustic impedance material layer 52 is about ¼ of an equivalent wavelength at a resonance frequency of each material layer. In addition, the thickness of the low acoustic impedance material layer close to the lower electrode layer may be properly adjusted according to the requirements for temperature compensation and device bandwidth.

In an embodiment, a material of the low acoustic impedance material layer 51 is a material having low acoustic impedance, which may be, but is not limited to, the same as a material of the temperature compensation layer 12, such as silicon dioxide, phosphosilicate glass, etc., or may also be another material, such as SiO₂, porous silicon, etc. A material of the high acoustic impedance material layer 52 is a material having high acoustic impedance, including but not limited to W, Mo, AlN, etc.

In summary, in the acoustic wave device of the third embodiment, the bulk acoustic wave device in the first region is of an SMR structure, and the acoustic reflection layer 5 and the piezoelectric structure are sequentially formed above the temperature compensation layer 12 in the first region to form the Bragg reflection, thereby rejecting the propagation of the acoustic wave energy toward the substrate 11 in the bulk acoustic wave device. It should be noted that, for the same portions as in the first embodiment, reference may be made to the descriptions of the first embodiment, which will not be repeated here.

### Fourth Embodiment

In a fourth exemplary embodiment of the present disclosure, an acoustic wave device is provided. Compared with the first embodiment, in the acoustic wave device of the fourth embodiment, a form of an upper electrode layer 22 is modified. In the present embodiment, the upper electrode layer 22 is no longer a planar electrode layer exemplified in the first embodiment, but an upper electrode layer 22′ of an inter-digital transducer structure.

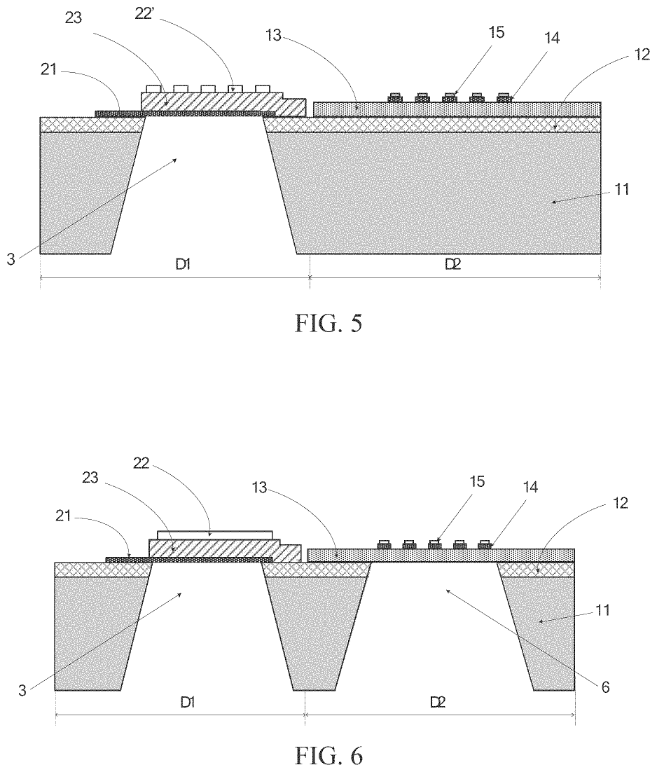

FIG. 5 is a schematic cross-sectional structure diagram of an acoustic wave device according to a fourth embodiment of the present disclosure.

Referring to FIG. 5, the acoustic wave device of the present embodiment includes:

a substrate 11; a temperature compensation layer 12 located above the substrate 11; a first piezoelectric layer 13 located above the temperature compensation layer 12 in a second region D2; an inter-digital transducer layer 14 located above the first piezoelectric layer 13;

a piezoelectric structure located above the temperature compensation layer 12 in a first region D1, there is a distance existing between the piezoelectric structure and the first piezoelectric layer 13, and a first cavity 3 is located below the piezoelectric structure; wherein the piezoelectric structure includes a lower electrode layer 21, a second piezoelectric layer 23 and an upper electrode layer 22′ of an inter-digital transducer structure that are stacked in sequence;

wherein a contour mode resonator (CMR) is formed in the first region D1, and a resonator of a surface acoustic wave (SAW) vibration mode is formed in the second region D2.

In the present embodiment, corresponding to the upper electrode 22′ of the piezoelectric structure in the first region D1 being of the inter-digital transducer structure, for example, the upper electrode 22 in the first embodiment may be patterned to form the upper electrode 22′ of the inter-digital transducer structure. An acoustic wave mode excited correspondingly in the first region D1 is a Lamb wave, and the CMR structure is formed corresponding to the first region D1.

A meaning of the Lamb wave is as follows: when an acoustic wave propagates in a thin plate, two boundary surfaces of the plate are affected, the acoustic wave is reflected on both two free boundaries, and the Lamb wave is formed after superposition.

The CMR device is formed in the first region D1, and the SAW is formed in the second region D2. Since the devices in the two regions have different vibration modes, the differences in the vibration modes may effectively reduce a coupling between the filters in the first region and second region, improve an attenuation and an isolation of the entire device, shorten a distance between the two filters, and also reduce the device size.

In other embodiments, the lower electrode 21 may not be grown in the piezoelectric structure, and only the upper electrode layer 22′ of the inter-digital transducer structure is used to excite the second piezoelectric layer 23 to vibrate. However, the equivalent coupling coefficient in this case is relatively small.

In some other embodiments, the CMR is formed in the first region D1, and the acoustic wave mode excited is the Lamb wave; and the solid mounted resonator (SMR) is formed in the second region D2, wherein a corresponding acoustic wave mode is also the Lamb wave as the upper electrode in the SMR is of an inter-digital structure rather than a thin film plate structure. In this way, the devices formed in the first region D1 and the second region D2 may have the same vibration modes. However, compared with an acoustic wave device where devices having different vibration modes are integrated in the two regions, as the vibration modes of the devices in the two regions are the same, it is easy to generate a vibration coupling with each other, and the isolation is relatively poor, resulting in a degraded performance.

In summary, in the acoustic wave device of the fourth embodiment, the device in the first region may be the CMR, the device in the second region may be the SAW. Alternatively, the vibration modes of the device in the first region and the device in the second region may be the same, for example, the device in the first region is the CMR, and the device in the second region is the SMR.

### Fifth Embodiment

In a fifth exemplary embodiment of the present disclosure, an acoustic wave device is provided. Compared with the first embodiment, in the acoustic wave device of the fifth embodiment, the second region D2 further includes a second cavity 6.

FIG. 6 is a schematic cross-sectional structural diagram of an acoustic wave device according to the fifth embodiment of the present disclosure.

Referring to FIG. 6, in the present embodiment, the acoustic wave device includes:

a substrate 11; a temperature compensation layer 12 located above the substrate 11; a first piezoelectric layer 13 located above the temperature compensation layer 12 in a second region D2; an inter-digital transducer layer 14 located above the first piezoelectric layer 13, a second cavity 6 is located below the first piezoelectric layer 13;

a piezoelectric structure located above the temperature compensation layer 12 in a first region D1, there is a distance existing between the piezoelectric structure and the first piezoelectric layer 13, and a first cavity 3 is located below the piezoelectric structure;

wherein a resonator of a bulk acoustic wave (BAW) vibration mode is formed in the first region D1, and one of a resonator of a surface acoustic wave (SAW) vibration mode and a contour mode resonator (CMR) is formed in the second region D2.

In the present embodiment, as shown in FIG. 6, the first cavity 3 is formed by releasing a portion of the temperature compensation layer 12 and the substrate 11 located below the piezoelectric structure. The second cavity 6 is formed by releasing a portion of the temperature compensation layer 12 and the substrate 11 located below the first piezoelectric layer 13. The first cavity and the second cavity may be completed in one same processing step, thereby saving manufacturing costs.

The piezoelectric structure includes a lower electrode layer 21, a second piezoelectric layer 23 and an upper electrode layer 22 that are stacked in sequence.

In the present embodiment, a vibration mode in the second region D2 may be a surface acoustic wave mode, such as an SH wave or a LOVE wave, or may also be a contour mode, such as a Lamb wave.

Here, the SH wave refers to a transverse wave where all particles vibrate horizontally in a wave propagation. The LOVE wave, also referred to as a Q wave or a ground roll wave, refers to a wave that vibrates in a direction perpendicular to the propagation direction in a horizontal plane, when a low velocity layer appears above a semi-wireless medium.

In summary, in the acoustic wave device of the present embodiment, the device in the first region corresponds to the BAW, and the second cavity is obtained by etching a portion of the temperature compensation layer and the substrate located below the first piezoelectric layer in the second region, such that, for example, a SAW of a SH wave mode or a LOVE wave mode, or a CMR based on a Lamb wave vibration is formed in the second region, thereby providing manners of combing more different modes.

### Sixth Embodiment

In a sixth exemplary embodiment of the present disclosure, an acoustic wave device is provided. Compared with the first embodiment, in the acoustic wave device of the sixth embodiment, the first cavity 3 is not formed. Compared with the third embodiment, in the acoustic wave device of the sixth embodiment, the acoustic reflection layer 5 is not necessarily provided, and the Bragg reflection layer is not formed. The device in a first region D1 in the present embodiment is neither the FBAR in the first embodiment nor the SMR in the third embodiment, but a high overtone acoustic resonator (HBAR).

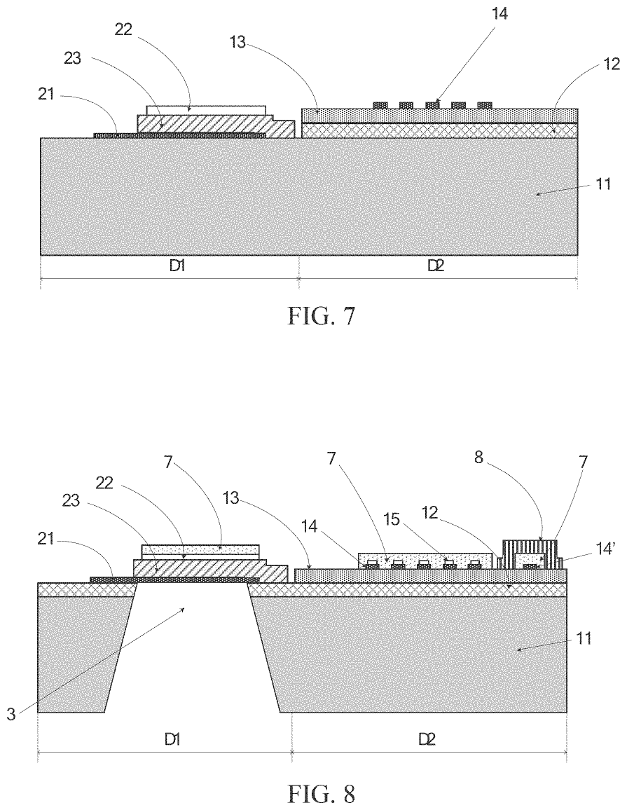

FIG. 7 is a schematic cross-sectional structural diagram of an acoustic wave device according to the sixth embodiment of the present disclosure.

Referring to FIG. 7, in the present embodiment, the acoustic wave device includes:

a substrate 11; a temperature compensation layer 12 located above the substrate 11 in a second region D2; a first piezoelectric layer 13 located above the temperature compensation layer 12; an inter-digital transducer layer 14 located above the first piezoelectric layer 13;

a piezoelectric structure located above the substrate 11 in the first region D1;

wherein the high overtone acoustic resonator (HBAR) is formed in the first region D1, and a resonator of a surface acoustic wave (SAW) vibration mode is formed in the second region D2.

In the present embodiment, the piezoelectric structure is located above the substrate 11 in the first region, and there is no other substantial layer or cavity existing between the piezoelectric structure and the substrate 11. In the formed HBAR device, an acoustic wave energy will propagate to the substrate and be reflected back, the HBAR device has a relatively high Q value and a very small equivalent coupling coefficient (k2eff), and may be used as an oscillator, a clock and the like. In this way, the first region D1 is an oscillator. In addition, the second region may be further divided into a plurality of (≥2) subregions to form different resonator devices, thereby forming a filter, a duplexer and a multiplexer etc. in the second region. A solution of dividing the second region into subregions will be exemplarily described in a seventh embodiment. An integration of various devices on the same POI structure is realized, and the devices have a good isolation from each other.

In summary, in the acoustic wave device of the present embodiment, the device in the first region corresponds to the HBAR, and may be used as an oscillator. The device in the second region is the SAW. It may be seen from the above embodiments that the device in the first region may be one of an SAW device (for example, FBAR or SMR) and an HBAR, and the device in the second region may be of a SAW or CMR structure. The situations of the first region and the second region may be freely combined. In addition, the second region may also be divided into a combination of a plurality of subregions in a manner described in any of the above embodiments, and different subregions may have same or different vibration modes. A combination form of subregions having different vibration modes or different vibration directions is preferred, so as to effectively reduce the coupling among the filters in each subregion, improve the attenuation and isolation of the entire device, shorten distances among the filters in each subregion, and reduce the device size.

Similarly, in each embodiments described above, the first region may also be divided into a plurality of subregions, and a concept is the same as the concept described above, which will not be described in detail here.

### Seventh Embodiment

In a seventh exemplary embodiment of the present disclosure, an acoustic wave device is provided. Compared with the first embodiment, the acoustic wave device of the present embodiment further includes a dielectric layer.

FIG. 8 is a schematic cross-sectional structural diagram of an acoustic wave device according to the seventh embodiment of the present disclosure.

Referring to FIG. 8, in the present embodiment, the acoustic wave device includes:

a substrate 11; a temperature compensation layer 12 located above the substrate 11; a first piezoelectric layer 13 located above the temperature compensation layer 12 in a second region D2; an inter-digital transducer layer 14 located above the first piezoelectric layer 13;

a piezoelectric structure located above the temperature compensation layer 12 in a first region D1, there is a distance existing between the piezoelectric structure and the first piezoelectric layer 13, and a first cavity 3 is located below the piezoelectric structure;

wherein an upper surface of the piezoelectric structure and the inter-digital transducer layer 14 are both covered with a dielectric layer 7;

wherein in the second region D2, another inter-digital transducer layer 14′ is further provided adjacent to the inter-digital transducer layer 14, the inter-digital transducer layer 14′ is configured as a third resonance portion, the inter-digital transducer layer 14 is configured as a second resonator, the first region forms a first resonator, and the second resonator and the third resonant portion constitute a of a temperature-compensated surface acoustic wave (TC-SAW) device.

Referring to FIG. 8, a metal layer 15 is further located above the inter-digital transducer layer 14. The metal layer 15 is located at an edge of an inter-digital transducer arm of the inter-digital transducer layer 14, and is of a bump structure relative to the inter-digital transducer layer 14. The dielectric layer 7 covers the inter-digital transducer layer 14 and the metal layer 15.

A material of the dielectric layer 7 includes, but is not limited to SiO₂, SiN, AlN etc. Taking SiO₂ as an example, a thicker dielectric layer 7 is grown on the inter-digital transducer 14′ configured as the third resonance portion to constitute a temperature-compensated surface acoustic wave (TC-SAW) device, which has a higher Q value and a better temperature coefficient of frequency (TCF) than a conventional surface acoustic wave device. The dielectric layer 7 may also be used as a frequency adjustment layer to further adjust a frequency of the first or second resonator, while protecting the upper electrode 22 of the first resonator, the metal layer 15 (when both are present)/inter-digital transducer layer 14 (when no metal layer is arranged) of the second resonator, and the inter-digital transducer layer 14′ of the third resonant portion from external pollution. A metal connection layer 8 is further provided on a periphery of the dielectric layer 7 of the third resonant portion.

A TC-SAW includes a resonator and a double mode saw (DMS). The DMS generally requires a dielectric bridge layer to isolate the inter-digital transducer layer 14 of the second resonator and the metal connection layer 8 of the third resonant portion. The dielectric bridge layer generally has a small dielectric coefficient to reduce a parasitic capacitance between signals. As shown in FIG. 8, the dielectric bridge layer in the second region may also multiplex the dielectric layer 7, thereby reducing the number of material layers and reducing the costs.

In summary, the present embodiment exemplarily describes a structure of dividing the second region into two subregions. Here, the two subregions in the second region constitute two associated portions of an integral device. In other embodiments, they may also be two independent device portions. Similarly, the first region may also be divided in a similar manner, which will not be described here.

### Eighth Embodiment

In an eighth exemplary embodiment of the present disclosure, an acoustic wave device is provided. Compared with the first embodiment, a formation manner of an acoustic velocity transition region in the present embodiment is different from that in the first embodiment.

FIG. 9 is a schematic top view structural diagram of an acoustic wave device according to the eighth embodiment of the present disclosure.

In the first embodiment, the metal layer is grown at the edge of the inter-digital transducer arm of the inter-digital transducer layer 14 to form the acoustic velocity transition region. However, in the present embodiment, as shown in FIG. 9, a high acoustic velocity layer 9 is grown in a middle region, an acoustic velocity at which a material of the high acoustic velocity layer 9 propagates is higher than an acoustic velocity at which the inter-digital transducer layer propagates, and an edge of the inter-digital transducer arm exposed in the edge region is correspondingly a low acoustic velocity region, such that an acoustic velocity transition region from a medium acoustic velocity to a low acoustic velocity, and then from the low acoustic velocity to a high acoustic velocity is formed along the extension direction of the inter-digital transducer arm, from the middle region to the edge region, and then from the edge region to an gap region. This helps to reduce an energy leakage of the acoustic waves in the extension direction of the inter-digital transducer arm, effectively reject a clutter mode near the resonance frequency, and improve a Q value of the device.

The high acoustic velocity layer is, for example, a dielectric material, and a material of the second piezoelectric layer 23 may be multiplexed, or a layer of dielectric material having a high acoustic velocity may be grown separately.

Referring to FIG. 9, the high acoustic velocity layer 9 not only covers the inter-digital transducer layer 14, but also covers the reflection grating 16, and thereby the middle region is covered by the high acoustic velocity layer.

In summary, in the acoustic wave device of the present embodiment, another manner of the acoustic velocity transition region is proposed to reject the clutter mode near the resonance frequency and improve the Q value of the device. The high acoustic velocity layer 9 is grown in the middle region, such that the inter-digital transducer arm of the edge region is exposed to form the acoustic velocity transition region.

### Ninth Embodiment

In a ninth exemplary embodiment of the present disclosure, a method of manufacturing an acoustic wave device is provided. In the present embodiment, a method of manufacturing the acoustic wave device shown in the first embodiment is taken as an example.

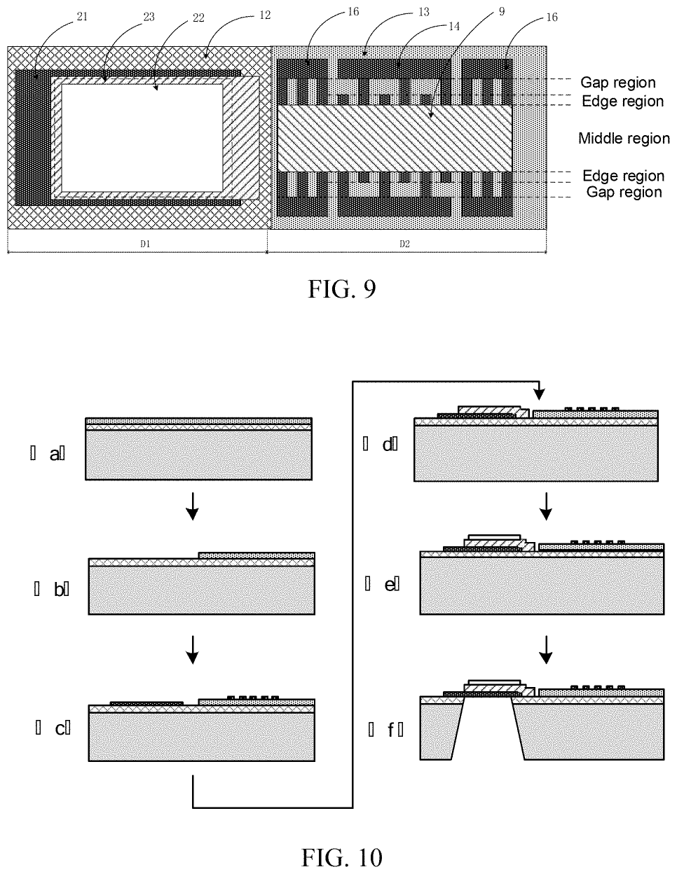

FIG. 10 is a method of manufacturing an acoustic wave device according to the ninth embodiment of the present disclosure.

Referring to (a)-(f) in FIG. 10, in the present embodiment, the method of manufacturing the acoustic wave device includes the steps as follows:

Step S21: a POI structure is manufactured, and a temperature compensation layer and a first piezoelectric layer are sequentially formed on a substrate;

a structure obtained by sequentially forming a temperature compensation layer 12 and a first piezoelectric layer 13 on s substrate 11 is as shown in FIG. 10(a).

Step S22: the first piezoelectric layer in a first region is removed so as to expose a portion of the temperature compensation layer;

the temperature compensation layer 12 located below the etched first piezoelectric layer 13 is exposed by etching the first piezoelectric layer 13 in the first region, thereby a structure obtained is as shown in FIG. 10(b).

Step S23: a piezoelectric structure is manufactured above the exposed temperature compensation layer; and an inter-digital transducer layer is manufactured above the first piezoelectric layer in a second region.

In the present embodiment, the process of manufacturing the piezoelectric structure above the exposed temperature compensation layer includes: sequentially manufacturing a lower electrode layer 21, a second piezoelectric layer 23 and an upper electrode layer 22 above the exposed temperature compensation layer; the process of manufacturing the inter-digital transducer layer 14 above the first piezoelectric layer 13 in the second region may be performed simultaneously with the process of manufacturing the lower electrode layer 21 or the upper electrode layer 22. For example, a metal material is deposited above the structure obtained in step S22, and the metal material is patterned, such that the metal material in the second region presents a pattern of the inter-digital transducer, a portion of the metal material in the first region is remained as the lower electrode layer 21, the rest of the metal material is etched, so as to obtain the structure as shown in FIG. 10(c). the lower electrode layer corresponding to this manner is multiplexed in a process of preparing a material of the inter-digital transducer layer; or a layer of metal material may be deposited to manufacture the inter-digital transducer layer after the preparation of the lower electrode layer is completed. After the manufacture of the lower electrode layer 21 is completed, forming a structure of the second piezoelectric layer 23 is as shown in FIG. 10(d); and further forming a structure of the upper electrode layer 22 is as shown in FIG. 10(e).

Step S24: a region located below the piezoelectric structure is released to obtain a first cavity.

In the present embodiment, the first cavity 3 is formed by etching (releasing) the substrate 11 and the temperature compensation layer 12 located below the piezoelectric structure. For example, a portion of the substrate 11 and the temperature compensation layer 12 located below the piezoelectric structure may be etched from a backside of the device by means of dry etching, so as to obtain a device structure including the first cavity 3 as shown in FIG. 10 (f).

Certainly, the preparation methods corresponding to the structures in other embodiments have been described during the descriptions of the structures, and the process of the present embodiment may be referred to realize the manufacture of the structures in other embodiments, which will not described in detail here.

It should be noted that it is also possible to directly grow the lower electrode layer on the surface of the first piezoelectric layer without etching the first piezoelectric layer in the first region, and finally etch the substrate, the temperature compensation layer and the first piezoelectric layer in the first region on the back side, so as to form a bulk acoustic wave device in the first region. However, at this time, the second piezoelectric layer is easily coupled with the first piezoelectric layer located below the lower electrode through the lower electrode layer, which affects the device performance. Therefore, it is preferred to etch a portion of the first piezoelectric layer, and then perform subsequent processes. In addition, if a lateral mode of the device in the second region is not severe, the metal layer 15 may not be grown.

In addition, it should be noted that the preparation processes are all within the protection scope of the present disclosure, as long as they may form the various structures and positional relationships as described above.

The acoustic wave device in the above embodiments may be used as a filter or a duplexer. For example, the filter or the duplexer may be designed through a ladder-type or lattice-type topological structure constituted by connecting several acoustic wave resonators, or through a DMS constituted by one or more IDTs that generate the acoustic energy.

In summary, the present disclosure provides an acoustic device. Comparing with a piezoelectric substrate of a conventional SAW device such as lithium niobate or lithium tantalate, by using the POI structure, an acoustic wave formed by a device vibration only propagates within the piezoelectric layer and the low acoustic velocity layer without leaking into a deeper substrate layer, and an energy leakage in a longitudinal direction is rejected. However, a portion of the energy still propagates outwardly in a lateral direction. Devices of at least two modes are integrated on one same device based on at least two regions, the implementation manner is simple and convenient. Moreover, by controlling the two modes to be different, the vibration modes or propagation directions are different, such that a coupling interference between devices in different regions may be reduced, and the rejection and isolation of filters or duplexers formed by a combination of devices in different regions may be improved. In this way, the device size may also be reduced, the costs may be reduced, and the requirements of communication miniaturization may be satisfied. Since piezoelectric materials of the same material and the same thickness do not need to be used for the devices of various vibration modes in the present disclosure, the degree of design freedom is improved. This is helpful to manufacture products that satisfy different bandwidths, different insertion losses, isolations, different power capacities, etc.

It should also be noted that although the present disclosure is described with reference to the accompanying drawings, the embodiments disclosed in the accompanying drawings are intended to illustrate the preferred embodiments of the present disclosure, and should not be construed as limiting the present disclosure. The size ratios in the drawings are only schematic, and should not be construed as limiting the present disclosure. The directional terms mentioned in the embodiments, such as “upper”, “lower”, “front”, “rear”, “left”, “right”, etc., only refer to the directions in the drawings, and are not intended to limit the protection scope of the present disclosure. Throughout the drawings, the same elements are represented by the same or similar reference signs. Conventional structures or constructions will be omitted when they may obscure the understanding of the present disclosure.

Moreover, the shapes and sizes of the components in the drawings do not reflect the actual sizes and proportions, but only illustrate the contents of the embodiments of the present disclosure. In addition, in the claims, any reference numeral in the parentheses should not be construed as limiting the claims.

Ordinal numbers such as “first”, “second”, and “third” used in the specification and the claims are used to describe corresponding elements, and they themselves do not mean that the elements have any ordinal number, nor do they represent orders of a certain element with another element, or orders in the manufacturing method. These ordinal numbers are used only to clearly distinguish an element with a certain name from another element with the same name.

Furthermore, the word “comprise” or “include” does not exclude a presence of an element or step not listed in the claims. The word “a”, “an” preceding an element does not exclude a presence of a plurality of such elements.

Unless technical obstacles or contradictions exist, the above various embodiments of the present disclosure may be freely combined to form additional embodiments, and these additional embodiments are all within the protection scope of the present disclosure.

The specific embodiments described above further describe the objectives, technical solutions and advantageous effects of the present disclosure in detail. It should be understood that the above are only specific embodiments of the present disclosure, and are not intended to limit the present disclosure. Any modification, equivalent replacement, improvement, etc. made within the spirit and principle of the present disclosure shall be included within the protection scope of the present disclosure.

What is claimed is:

1. An acoustic wave device, comprising:
a POI structure comprising: a material layer where a high acoustic velocity layer and a low acoustic velocity layer are alternate, wherein a substrate is a lowermost high acoustic velocity layer; and a first piezoelectric layer located above the material layer where the high acoustic velocity layer and the low acoustic velocity layer are alternate, wherein a layer adjacent to the first piezoelectric layer is referred to as a surface low acoustic velocity layer; wherein an acoustic velocity of a bulk wave propagated in the high acoustic velocity layer is higher than an acoustic velocity of a bulk wave of the first piezoelectric layer, and an acoustic velocity of a bulk wave propagated in the low acoustic velocity layer is lower than the acoustic velocity of the bulk wave of the first piezoelectric layer;
wherein the POI structure comprises at least two regions, the two regions are respectively a first region and a second region, a first device having a resonance of a first vibration mode is manufactured in the first region, and a second device having a resonance of a second vibration mode is manufactured in the second region.

2. The acoustic wave device according to claim 1, wherein the first vibration mode and the second vibration mode are a combination of any two types of a bulk acoustic wave (BAW) vibration mode, a surface acoustic wave (SAW) vibration mode, and a contour mode resonator (CMR) mode.

3. The acoustic wave device according to claim 2, wherein the first vibration mode and the second vibration mode are different vibration modes.

4. The acoustic wave device according to claim 1, wherein
the first piezoelectric layer is located above the surface low acoustic velocity layer in the second region;
an inter-digital transducer layer is located above the first piezoelectric layer; and
a piezoelectric structure is located above the surface low acoustic velocity layer in the first region, there is a distance existing between the piezoelectric structure and the first piezoelectric layer, and a first cavity is located below the piezoelectric structure;
wherein the piezoelectric structure comprises a lower electrode layer, a second piezoelectric layer, and an upper electrode layer that are stacked in sequence.

5. The acoustic wave device according to claim 4, wherein the upper electrode layer is of a thin film structure or an inter-digital transducer structure.

6. The acoustic wave device according to claim 4, wherein a second cavity is located below the first piezoelectric layer, and the second cavity is formed by releasing a portion of the surface low acoustic velocity layer and the substrate located below the first piezoelectric layer.

7. The acoustic wave device according to claim 4, wherein
an upper surface of the piezoelectric structure and the inter-digital transducer layer are both covered with a dielectric layer;
the second region comprises two subregions, which are respectively a first subregion and a second subregion, the inter-digital transducer layer is located in the first subregion, another inter-digital transducer layer is located in the second subregion, and the another inter-digital transducer layer is sequentially covered with a dielectric layer and a metal connection layer.

8. The acoustic wave device according to anyone of claim 4, wherein
a metal layer is further arranged on the inter-digital transducer layer, and the metal layer is located at an edge of an inter-digital transducer arm of the inter-digital transducer layer; or
a second high acoustic velocity layer is formed in a middle region of the inter-digital transducer layer, and an acoustic velocity of a bulk wave propagated in the second high acoustic velocity layer is higher than the acoustic velocity of the bulk wave of the first piezoelectric layer.

9. The acoustic wave device according to claim 4, wherein
the first cavity is formed by releasing a portion of the surface low acoustic velocity layer and the substrate located below the piezoelectric structure; or
the first cavity is formed by releasing a portion of the surface low acoustic velocity layer located below the piezoelectric structure, and a periphery of the first cavity located below the piezoelectric structure is a barrier layer.

10. The acoustic wave device according to claim 1, wherein
the device in the first region is a bulk acoustic wave device, the bulk acoustic wave device is of an SMR structure, an acoustic reflection layer comprising a low acoustic impedance material layer and a high acoustic impedance material layer that are stacked alternately is located above the first piezoelectric layer in the first region; the piezoelectric structure is located above the low acoustic impedance material layer of the acoustic reflection layer; or
the device in the first region is a high overtone acoustic resonator, and the device in the second region is one or a combination of the following devices: a resonator of a bulk acoustic wave (BAW) vibration mode, a resonator of a surface acoustic wave (SAW) vibration mode, and a contour mode resonator (CMR), wherein the resonator of a bulk acoustic wave (BAW) vibration mode comprises one or a combination of the following resonators: a film bulk acoustic resonator (FBAR) and a solid mounted resonator (SMR).

11. The acoustic wave device according to claim 1, wherein all or a portion of the devices in at least two regions of the acoustic wave devices are served as filters or duplexers.

12. The acoustic wave device according to anyone of claim 1, wherein the surface low acoustic velocity layer is a temperature compensation layer, and a material of the temperature compensation layer is a dielectric material having a positive frequency temperature coefficient.

13. A method of manufacturing the acoustic wave device according to claim 1, comprising:
manufacturing a POI structure, wherein the POI structure comprises: a material layer where a high acoustic velocity layer and a low acoustic velocity layer are alternate, and a substrate is a lowermost high acoustic velocity layer; and a first piezoelectric layer located above the material layer where the high acoustic velocity layer and the low acoustic velocity layer are alternate, and a layer adjacent to the first piezoelectric layer is referred to as a surface low acoustic velocity layer; wherein an acoustic velocity of a bulk wave propagated in the high acoustic velocity layer is higher than an acoustic velocity of a bulk wave of the first piezoelectric layer, and an acoustic velocity of a bulk wave propagated in the low acoustic velocity layer is lower than the acoustic velocity of the bulk wave of the first piezoelectric layer;
wherein the POI structure comprises at least two regions, the two regions are respectively a first region and a second region, a first device having a resonance of a first vibration mode is manufactured in the first region, and a second device having a resonance of a second vibration mode is manufactured in the second region.

14. A method of manufacturing the acoustic wave device according to claim 4, comprising:
manufacturing a POI structure, wherein the POI structure comprises: a material layer where a high acoustic velocity layer and a low acoustic velocity layer are alternate, and a substrate is a lowermost high acoustic velocity layer; and a first piezoelectric layer located above the material layer where the high acoustic velocity layer and the low acoustic velocity layer are alternate, and a layer adjacent to the first piezoelectric layer is referred to as a surface low acoustic velocity layer; wherein an acoustic velocity of a bulk wave propagated in the high acoustic velocity layer is higher than an acoustic velocity of a bulk wave of the first piezoelectric layer, and an acoustic velocity of a bulk wave propagated in the low acoustic velocity layer is lower than the acoustic velocity of the bulk wave of the first piezoelectric layer;
the POI structure comprises at least two regions, wherein the two regions are respectively a first region and a second region, and a first piezoelectric layer in the first region is etched to expose the surface low acoustic velocity layer;
manufacturing a piezoelectric structure on the exposed surface low acoustic velocity layer, wherein there is a distance existing between the piezoelectric structure and the first piezoelectric layer; wherein the piezoelectric structure comprises a lower electrode layer, a second piezoelectric layer and an upper electrode layer that are stacked in sequence;
manufacturing an inter-digital transducer layer on the first piezoelectric layer in the second region; and
releasing a portion of the surface low acoustic velocity layer and the substrate located below the piezoelectric structure to form a first cavity, and obtaining a first device having a resonance of a first vibration mode in the first region, and obtaining a second device having a resonance of a second vibration mode in the second region.

15. A method of manufacturing the acoustic wave device according to claim 4, comprising:
manufacturing a POI structure, wherein the POI structure comprises: a material layer where a high acoustic velocity layer and a low acoustic velocity layer are alternate, and a substrate is a lowermost high acoustic velocity layer; and a first piezoelectric layer located above the material layer where the high acoustic velocity layer and the low acoustic velocity layer are alternate, and a layer adjacent to the first piezoelectric layer is referred to as a surface low acoustic velocity layer; wherein an acoustic velocity of a bulk wave propagated in the high acoustic velocity layer is higher than an acoustic velocity of a bulk wave of the first piezoelectric layer, and an acoustic velocity of a bulk wave propagated in the low acoustic velocity layer is lower than the acoustic velocity of the bulk wave of the first piezoelectric layer;
wherein the POI structure comprises at least two regions, wherein the two regions are respectively a first region and a second region, and a first piezoelectric layer in the first region is etched to expose the surface low acoustic velocity layer;
etching a portion of the surface low acoustic velocity layer to obtain an annular hollow region, and growing a barrier layer in the annular hollow region, wherein a material of the barrier layer has a different etching rate with a material of the surface low acoustic velocity layer;
manufacturing a piezoelectric structure on the surface low acoustic velocity layer in the first region, wherein there is a distance existing between the piezoelectric structure and the first piezoelectric layer; wherein the piezoelectric structure comprises a lower electrode layer, a second piezoelectric layer and an upper electrode layer that are stacked in sequence;
manufacturing an inter-digital transducer layer on the first piezoelectric layer in the second region;
etching the surface low acoustic velocity layer located on an inner side of the barrier layer as a sacrificial layer based on the difference in the etching rates to form a first cavity; and
obtaining a first device having a resonance of a first vibration mode in the first region, and a second device having a resonance of a second vibration mode in the second region.

16. The method of manufacturing the acoustic wave device according to claim 14, wherein
the inter-digital transducer layer is manufactured by multiplexing a material and a thickness of the lower electrode layer; or
the inter-digital transducer layer is manufactured by separately growing a layer of electrode material.
